(19) United States
(12) Patent Application Publication
(10) Pub. No.: US 2024/0071766 A2
(43) Pub. Date: Feb. 29, 2024

(54) METHODS FOR FILLING A GAP FEATURE ON A SUBSTRATE SURFACE AND RELATED SEMICONDUCTOR STRUCTURES

(71) Applicant: ASM IP Holding B.V., Almere (NL)

(72) Inventors: Kunal Bhatnagar, Chandler, AZ (US); Ashwin Agathya Boochakravarthy, Fremont, CA (US); Wei Li, Chandler, AZ (US)

(21) Appl. No.: 17/073,544

(22) Filed: Oct. 19, 2020

Related U.S. Application Data
(60) Provisional application No. 62/926,309, filed on Oct. 25, 2019.

(51) Int. Cl. H01L 21/28; H01L 29/423; H01L 29/49

(52) U.S. Cl. CPC H01L 21/28088; H01L 29/4236; H01L 29/4966

(57) ABSTRACT

Methods for filling a gap feature on a substrate surface are disclosure. The methods may include: providing a substrate comprising one or more gap features into a reaction chamber; and depositing a metallic gap-fill film within the gap feature by performing repeated unit cycles of a cyclical deposition process. Semiconductor structures including metallic gap-fill films are also disclosed.

This application is a Non-provisional of, and claims priority to and the benefit of, U.S. Provisional Patent Application No. 62/926,309, filed on Oct. 25, 2019 and entitled “METHODS FOR FILLING A GAP FEATURE ON A SUBSTRATE SURFACE AND RELATED SEMICONDUCTOR STRUCTURES,” which is hereby incorporated by reference herein.

### FIELD OF INVENTION

The present disclosure relates generally to methods for filling a gap feature on a substrate surface and particularly methods for filling one or more gap features with a metallic gap-fill film utilizing cyclical deposition processes. The present disclosure also generally relates to semiconductor structures including one or more gap features filled with a metallic gap-fill film.

### BACKGROUND OF THE DISCLOSURE

Semiconductor fabrication processes for forming semiconductor device structures, such as, for example, transistors, memory elements, and integrated circuits, are wide ranging and may include deposition processes, etch processes, thermal annealing processes, lithography processes, and doping processes, amongst others.

A particular semiconductor fabrication process commonly utilized is the deposition of a metallic film into a gap feature thereby filling the gap feature with the metallic film, a process commonly referred to as “gap-fill.” Semiconductor substrates may comprise a multitude of gap features on a substrate with a non-planar surface. The gap features may comprise vertical gap features being disposed between protruding portions of the substrate surface or indentations formed in a substrate surface. The gap features may also comprise horizontal gap features being disposed between two adjacent materials bounding the horizontal gap feature.

As semiconductor device structure geometries with high aspect ratio features have become more common place in such semiconductor device structures as DRAM, flash memory, and logic, it has become increasingly difficult to fill the multitude of gap features with metallic films having the desired characteristics.

Accordingly, deposition methods and associated semiconductor structures are desired for filling gap features on a non-planar substrate with a metallic gap-fill film.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In some embodiments, methods for filling a gap feature on a substrate surface are provided. The methods may comprise: providing a substrate comprising a gap feature into a reaction chamber; and filling the gap feature with a metal nitride film by performing one or more unit cycles of a cyclical deposition process, wherein a unit cycle of the cyclical deposition process comprises: contacting the substrate a metal precursor; contacting the substrate with a nitrogen precursor; and contacting the substrate with a halide growth inhibitor.

The embodiments of the disclosure may also include methods for filling a vertical gap feature on a substrate surface. The methods may comprise: providing a substrate comprising a vertical gap feature into a reaction chamber configured for a cyclical deposition process; depositing a metal nitride film within the vertical gap feature by performing repeated unit cycles of a non-conformal cyclical deposition process, wherein a unit cycle of the non-conformal cyclical deposition process comprises: contacting the substrate with a metal halide precursor; contacting the substrate with a nitrogen precursor; and contacting the substrate with a halide growth inhibitor; and filling the vertical gap feature with the metal nitride film; wherein the halide growth inhibitor is provided from both an internal source within the reaction chamber and an external source, remote from the reaction chamber, fluidly connected to the reaction chamber.

The embodiments of the disclosure may also include methods for filling a gap feature on a substrate surface. The methods may comprise: providing a substrate comprising a gap feature into a reaction chamber configured for a cyclical deposition process; depositing a metallic gap-fill film comprising at least one of a metal nitride film, a metal oxide film, a metal carbide film, or a metal silicide film, within the gap feature by performing repeated unit cycles of a non-conformal cyclical deposition process, wherein a unit cycle of the non-conformal cyclical deposition process comprises: contacting the substrate with a metal halide precursor; contacting the substrate with at least one of a nitrogen precursor, an oxygen precursor, a carbon precursor, or a silicon precursor; and contacting the substrate with a halide growth inhibitor; and filling the gap feature with the metallic gap-fill film; wherein the halide growth inhibitor is provided from both an internal source within the reaction chamber and an external source, remote from the reaction chamber, fluidly connected to the reaction chamber.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWING FIGURES

While the specification concludes with claims particularly pointing out and distinctly claiming what are regarded as embodiments of the invention, the advantages of embodiments of the disclosure may be more readily ascertained from the description of certain examples of the embodiments of the disclosure when read in conjunction with the accompanying drawings, in which:

FIG. 1 illustrates a simplified cross-sectional schematic diagram of an exemplary gap feature filled with a metallic gap-fill film which includes an undesirable seam;

FIG. 2 illustrates a non-limiting exemplary process flow, demonstrating a method for filling a gap feature on a surface of a substrate with a metallic gap-fill film according to the embodiments of the disclosure;

FIG. 3 illustrates exemplary experimental data demonstrating the decrease in growth rate per cycle for a cyclical deposition process as a function of the contact time between a substrate surface and a halide growth inhibitor according to the embodiments of the disclosure;

FIGS. 4A-4C illustrate simplified cross-sectional schematic diagrams of semiconductor structures formed during cyclical deposition processes according to the embodiments of the disclosure; and

FIGS. 5A and 5B illustrate simplified cross-section schematic diagrams of exemplary semiconductor structures including vertical gap features with differing geometries filled with a metallic gap-fill film according to the embodiments of the disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

The illustrations presented herein are not meant to be actual views of any particular material, structure, or device, but are merely idealized representations that are used to describe embodiments of the disclosure.

As used herein, the term “substrate” may refer to any underlying material or materials that may be used, or upon which, a device, a circuit, or a film may be formed.

As used herein, the term “cyclic deposition” may refer to the sequential introduction of two or more precursors (reactants) into a reaction chamber to deposit a film over a substrate and includes deposition techniques such as, but not limited to, atomic layer deposition and cyclical chemical vapor deposition.

As used herein, the term “cyclical chemical vapor deposition” may refer to any process wherein a substrate is sequentially exposed to two or more volatile precursors, which react and/or decompose on a substrate to produce a desired deposition.

As used herein, the term “atomic layer deposition” (ALD) may refer to a vapor deposition process in which deposition cycles, preferably a plurality of consecutive unit deposition cycles, are conducted in a reaction chamber. Typically, during each unit cycle the precursor is chemisorbed to a deposition surface (e.g., a substrate surface or a previously deposited underlying surface such as material from a previous ALD cycle), forming a monolayer or sub-monolayer that does not readily react with additional precursor (i.e., a self-limiting reaction). Thereafter, if necessary, a reactant (e.g., another precursor or reaction gas) may subsequently be introduced into the process chamber for use in converting the chemisorbed precursor to the desired material on the deposition surface. Typically, this reactant is capable of further reaction with the precursor. Further, purging steps may also be utilized during each cycle to remove excess precursor from the process chamber and/or remove excess reactant and/or reaction byproducts from the process chamber after conversion of the chemisorbed precursor. Further, the term “atomic layer deposition,” as used herein, is also meant to include processes designated by related terms such as, “chemical vapor atomic layer deposition,” “atomic layer epitaxy” (ALE), molecular beam epitaxy (MBE), gas source MBE, or organometallic MBE, and chemical beam epitaxy when performed with alternating pulses of precursor composition(s), reactive gas, and purge (e.g., inert carrier) gas.

As used herein, the term “film” may refer to any continuous or non-continuous structures and material formed by the methods disclosed herein. For example, “film” could include 2D materials, nanolaminates, nanorods, nanotubes, or nanoparticles, or even partial or full molecular layers, or partial or full atomic layers or clusters of atoms and/or molecules. “Film” may comprise material or a layer with pinholes, but still be at least partially continuous.

As used herein, the term “halide growth inhibitor” may refer to a vapor phase reactant which comprises a halide component, such as, for example, a chlorine component, an iodine component, or a bromine component. The “halide growth inhibitor” may, when introduced into a reaction chamber to contact an exposed surface of a substrate, at least partially inhibit the growth (or deposition) of a metallic gap-fill film over portions of the substrate surface contacted with the “halide growth inhibitor.”

As used herein, the term “metal nitride film” may refer to a film comprising at least a metal component and a nitrogen component. The term “metal nitride film” may include binary metal nitride films, as well as ternary metal nitride films, and quaternary metal nitride films.

As used herein, the term “gap feature” may refer to an opening or cavity disposed between two surfaces of a non-planar surface. The term “gap feature” may refer to an opening or cavity disposed between opposing inclined sidewalls of two protrusions extending vertically from the surface of the substrate or opposing inclined sidewalls of an indentation extending vertically into the surface of the substrate, such a gap feature may be referred to as a “vertical gap feature.” The term “gap feature” may also refer to an opening or cavity disposed between two opposing substantially horizontal surfaces, the horizontal surfaces bounding the horizontal opening or cavity; such a gap feature may be referred to as a “horizontal gap feature.”

As used herein, the term “seam” may refer to a line or one or more voids formed by the abutment of edges formed in a metallic gap-fill film, and the “seam” can be confirmed using a scanning transmission electron microscopy (STEM) or transmission electron microscopy (TEM) wherein if observations reveals a clear vertical line or one or more voids in a vertical gap-fill metallic film, or a clear horizontal line or one or more horizontal voids in a horizontal gap-fill metallic film then a “seam” is present.

As used herein, the term “metal halide precursor” may refer to a precursor comprising at least a metal component and a halide component, such as, for example, a chlorine component, a iodine component, or a bromine component. The term “metal halide precursor” may in addition refer to precursor including addition components, such as, for example, an oxygen component, a silicon component, and a carbon component.

As used herein, the term “non-conformal deposition” may refer to a deposition process in which the deposited film is characterized by a non-uniform average film thickness over a non-planar substrate surface.

In the specification, it will be understood that the term “on” or “over” may be used to describe a relative location relationship. Another element or layer may be directly on the mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly to this, it will be understood the term “under,” “underlying,” or “below” will be construed to be relative concepts.

A number of example materials are given throughout the embodiments of the current disclosure, it should be noted that the chemical formulas given for each of the example materials should not be construed as limiting and that the non-limiting example materials given should not be limited by a given example stoichiometry.

The present disclosure includes methods for filling a gap feature on a substrate surface and particularly methods for filling one or more gap features with a metallic gap-fill film utilizing cyclical deposition processes.

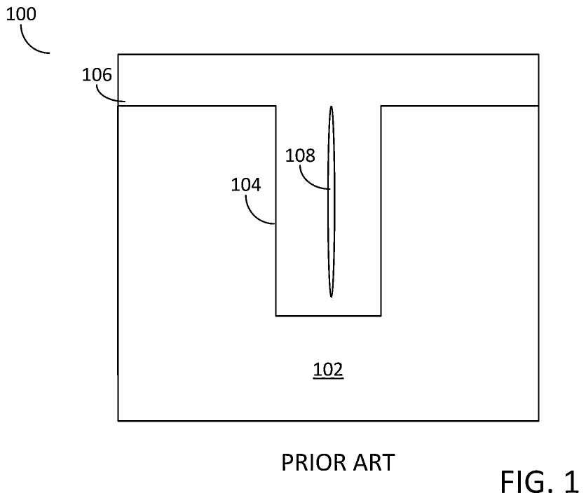

An example of a semiconductor structure including a gap feature filled with a metallic gap-fill film by previously known methods is illustrated in FIG. 1.

In more detail, FIG. 1 illustrates a simplified cross-sectional schematic diagram of a semiconductor structure 100 comprising a substrate 102 including a vertical gap feature 104, the vertical gap feature 104 being filled with a metallic gap-fill film 106. As illustrated in FIG. 1, disposed within the metallic gap-fill film 106 is a feature commonly referred to as a seam 108. A seam refers to a region in the metallic gap-fill film 106 where the edges of two films growing from both sidewalls of the vertical gap feature contact each other; therefore, the seam 108 is commonly disposed at the center of the vertical gap feature 104. The formation of a seam 108 in the metallic gap-fill film is undesirable and may result in poor device performance and subsequent issues in semiconductor device fabrication processes. In the illustrated example, the seam 108 may comprise a vertical line or one or more voids that may be observable using scanning transmission electron microscopy (STEM) or transmission electron microscopy (TEM) where, if observations reveal a vertical line or one or voids in the metallic gap-fill film 106, then a seam 108 is present.

Accordingly, deposition methods and related semiconductor structures are desirable that enable the filling of one or more gap features with a metallic gap-fill film without the formation of a seam.

Therefore, the embodiments of the disclosure may include methods for filling a gap feature on a substrate surface. The methods may comprise: providing a substrate comprising a gap feature into a reaction chamber; and filling the gap feature with a metal nitride film by performing one or more unit cycles of a cyclical deposition process, wherein a unit cycle of the cyclical deposition process comprises: contacting the substrate with a metal precursor; contacting the substrate with a nitrogen precursor; and contacting the substrate with a halide growth inhibitor.

The embodiments of the disclosure may also include methods for filling a vertical gap feature on a substrate surface. The methods may comprise: providing a substrate comprising a vertical gap feature into a reaction chamber configured for a cyclical deposition process; depositing a metal nitride film within the vertical gap feature by performing repeated unit cycles of a non-conformal cyclical deposition process, wherein a unit cycle of the non-conformal cyclical deposition process comprises: contacting the substrate with a metal halide precursor; contacting the substrate with a nitrogen precursor; and contacting the substrate with a halide growth inhibitor; and filling the vertical gap feature with the metal nitride film; wherein the halide growth inhibitor is provided from both an internal source within the reaction chamber and an external source, remote from the reaction chamber, fluidly connected to the reaction chamber.

The embodiments of the disclosure may also include additional methods for filling a gap feature on a substrate surface. The methods may comprise: providing a substrate comprising a gap feature into a reaction chamber configured for a cyclical deposition process; depositing a metallic gap-fill film comprising at least one of a metal nitride film, a metal oxide film, a metal carbide film, or a metal silicide film, within the gap feature by performing repeated unit cycles of a non-conformal cyclical deposition process, wherein a unit cycle of the non-conformal cyclical deposition process comprises: contacting the substrate with a metal halide precursor; contacting the substrate with at least one of a nitrogen precursor, an oxygen precursor, a carbon precursor, or a silicon precursor; and contacting the substrate with a halide growth inhibitor; and filling the gap feature with the metallic gap-fill film; wherein the halide growth inhibitor is provided from both an internal source within the reaction chamber and an external source, remote from the reaction chamber, fluidly connected to the reaction chamber.

A non-limiting example embodiment of a cyclical deposition process may include atomic layer deposition (ALD), wherein ALD is based on typically self-limiting reactions, whereby sequential and alternating pulses of precursors are used to deposit about one atomic (or molecular) monolayer of material per deposition cycle. The deposition conditions and precursors are typically selected to provide self-saturating reactions, such that an absorbed layer of one precursor leaves a surface termination that is non-reactive with the gas phase reactants of the same reactants. The substrate is subsequently contacted with a different precursor that reacts with the previous termination to enable continued deposition. Thus, each cycle of alternated pulses typically leaves no more than about one monolayer of the desired material. However, as mentioned above, the skilled artisan will recognize that in one or more ALD cycles more than one monolayer of material may be deposited, for example, if some gas phase reactions occur despite the alternating nature of the process.

As a non-limiting example, for the cyclical gap-fill deposition processes of the present disclosure, one deposition cycle, i.e., a unit deposition cycle, may comprise exposing the substrate to a first vapor phase reactant, removing any unreacted first reactant from the reaction chamber, exposing the substrate to a second vapor phase reactant, followed by a second removal step, and exposing the substrate to a halide growth inhibitor, followed by a third removal phase. In a particular non-limiting example wherein a cyclical deposition process is employed to deposit a titanium nitride gap-fill film, the first vapor phase reactant may comprise a titanium halide precursor, the second vapor phase reactant may comprise a nitrogen precursor, and a halide growth inhibitor may comprise hydrochloric acid (HCl) vapor, for example.

Precursors may be separated by inert gases, such as argon (Ar) or nitrogen (N₂), to prevent gas-phase reactions between reactants and enable self-saturating surface reactions. In some embodiments, however, the substrate may be moved to separately contact a first vapor phase reactant and a second vapor phase reactant. Because the reactions self-saturate, strict temperature control of the substrates and precise dosage control of the precursors may not be required. However, the substrate temperature is preferably such that an incident gas species does not condense into monolayers nor decompose on the surface. Surplus precursor and vapor phase halide growth inhibitor may be removed from the substrate surface by employing a purge cycle, such as, by introducing an inert purge gas into the reaction chamber and exhausting the reaction chamber with the aid of a vacuum pump in fluid communication with the reaction chamber, for example.

In some embodiments, of the disclosure, a unit deposition cycle of the cyclical deposition processes of the current disclosure may comprise three or more distinct deposition steps or stages. In a first stage of the unit deposition cycle (“the metal stage”), the substrate surface on which deposition is desired may be contacted with a first vapor phase reactant comprising a metal halide precursor which chemisorbs on to the surface of the substrate, forming no more than about one monolayer of reactant species on the surface of the substrate. In a second stage of the deposition, the substrate surface on which deposition is desired may be contacted with a second vapor phase reactant comprising one of a nitrogen precursor, an oxygen precursor, a carbon precursor, or a silicon precursor. In a third stage of the deposition (“the inhibitor phase”), the substrate surface on which deposition is desired may be contacted with a vapor phase halide growth inhibitor, such as, hydrochloric acid (HCl) vapor, for example.

In some embodiments, the cyclical deposition processes of the current disclosure may comprise a hybrid ALD/CVD process, or a cyclical CVD process. For example, in some embodiments, the growth rate of a particular ALD process may be low compared with a CVD process. One approach to increase the growth rate may be that of operating at a higher deposition temperature than that typically employed in an ALD process, resulting in some portion of a chemical vapor deposition process, but still taking advantage of the sequential introduction of reactants, such a process may be referred to as cyclical CVD. In some embodiments, a cyclical CVD process may comprise the introduction of two or more reactants into the reaction chamber wherein there may be a time period of overlap between the two or more reactants in the reaction chamber resulting in both an ALD component of the deposition and a CVD component of the deposition. For example, a cyclical CVD process may comprise the continuous flow of a one reactant and the periodic pulsing of a second reactant into the reaction chamber.

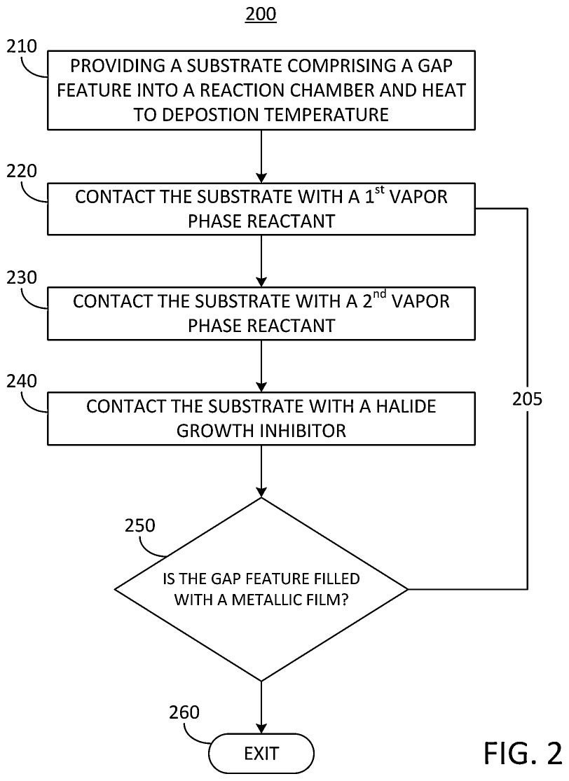

An exemplary cyclical deposition process for filling one or more gap features on a substrate is illustrated with reference to exemplary cyclical deposition process 200 of FIG. 2. In more detail, the exemplary metallic gap-fill film deposition process 200 may commence by means of a process block 210 which comprises, providing a substrate comprising a gap feature into a reaction chamber and heating the substrate to a desired deposition temperature.

In some embodiments of the disclosure, the substrate may comprise a patterned substrate including high aspect ratio features, such as, for example, vertical gap features and/or horizontal gap features. In particular embodiments, a patterned substrate may comprise a non-planar surface include one or more vertical gap features (or vertical non-linear features). For example, the term “vertical gap feature” may comprise: an opening or cavity disposed between opposing inclined sidewalls of two protrusions extending upwards from a surface of a substrate, or opposing inclined sidewalls of an indentation extending downward into a surface of a substrate. Non-limiting examples of “vertical gap features” may include, but is not limited to: v-shaped vertical trenches, tapered vertical trenches, re-entrant vertical trenches, vertical openings, vertical voids, and vertical through-silicon-via trenches. For example, a vertical gap feature may comprise adjacent sidewalls which meet at a point at the base of the feature, or a vertical gap feature may comprise opposing inclined sidewalls that plateau to a flat base surface. “Vertical” as used herein does not limit the slope of opposing sidewalls specifically to a perpendicular incline with the horizontal plane of the substrate.

In some embodiments of the disclosure, the substrate may comprise one or more vertical gap features, wherein the vertical gap features may have an aspect ratio (height:width) which may be greater than 2:1, or greater than 5:1, or greater than 10:1, or greater than 25:1, or greater than 50:1, or even greater than 100:1, wherein “greater than” as used in this example refers to a greater distance in the height of the gap feature. In some embodiments of the disclosure, the substrate may comprise one or more horizontal gap features, wherein the horizontal gap features may have an aspect ratio (height:width) which may be greater than 1:2, or greater than 1:5, or greater than 1:10, or greater than 1:25, or greater than 1:50, or even greater than 1:100, wherein “greater than” as used in this example refers to a greater distance in the width of the gap feature. In some embodiments, a substrate may comprise a plurality of vertical gap features with common and differing aspect ratios.

The substrate may comprise one or more materials and material surfaces including, but not limited to, semiconductor materials, dielectric materials, and metallic materials.

In some embodiments, the substrate may include semiconductor materials, such as, but not limited to, silicon (Si), germanium (Ge), germanium tin (GeSn), silicon germanium (SiGe), silicon germanium tin (SiGeSn), silicon carbide (SiC), or a group III-V semiconductor materials.

In some embodiments, the substrate may include metallic materials, such as, but not limited to, pure metals, metal nitrides, metal carbides, metal borides, and mixtures thereof.

In some embodiments, the substrate may include dielectric materials, such as, but not limited, to silicon containing dielectric materials and metal oxide dielectric materials. In some embodiments, the substrate may comprise one or more dielectric surfaces comprising a silicon containing dielectric material such as, but not limited to, silicon dioxide (SiO₂), silicon sub-oxides, silicon nitride (Si₃N₄), silicon oxynitride (SiON), silicon oxycarbide (SiOC), silicon oxycarbide nitride (SiOCN), silicon carbon nitride (SiCN). In some embodiments, the substrate may comprise one or more dielectric surfaces comprising a metal oxide such as, but not limited to, aluminum oxide (Al₂O₃), hafnium oxide (HfO₂), tantalum oxide (Ta₂O₅), zirconium oxide (ZrO₂), titanium oxide (TiO₂), hafnium silicate (HfSiOₓ), and lanthanum oxide (La₂O₃).

In some embodiments of the disclosure, the substrate may comprise an engineered substrate wherein a surface semiconductor layer is disposed over a bulk support with an intervening buried oxide (BOX) disposed there between.

Patterned substrates may comprise substrates that may include semiconductor device structures formed into or onto a surface of the substrate, for example, a patterned substrate may comprise partially fabricated semiconductor device structures, such as, for example, transistors and/or memory elements. In some embodiments, the substrate may contain monocrystalline surfaces and/or one or more secondary surfaces that may comprise a non-monocrystalline surface, such as a polycrystalline surface and/or an amorphous surface. Monocrystalline surfaces may comprise, for example, one or more of silicon (Si), silicon germanium (SiGe), germanium tin (GeSn), or germanium (Ge). Polycrystalline or amorphous surfaces may include dielectric materials, such as oxides, oxynitrides, oxycarbides, oxycarbide nitrides, nitrides, or mixtures thereof.

Reactors and associated reaction chambers capable of the cyclical deposition processes of the current disclosure may include atomic layer deposition (ALD) reactors and appropriately configured ALD reaction chambers, as well as chemical vapor deposition (CVD) reactors and appropriately configured CVD reaction chambers constructed and arranged to provide the precursors. According to some embodiments, a showerhead reactor may be used. According to some embodiments, cross-flow, batch, minibatch, or spatial ALD reactors may be used.

In some embodiments of the disclosure, a batch reactor may be used. In some embodiments, a vertical batch reactor may be used. In other embodiments, a batch reactor comprises a minibatch reactor configured to accommodate 10 or fewer wafers, 8 or fewer wafers, 6 or fewer wafers, 4 or fewer wafers, or 2 or fewer wafers. In some embodiments in which a batch reactor is used, wafer-to-wafer non-uniformity is less than 3% (1 sigma), less than 2%, less than 1%, or even less than 0.5%.

The exemplary cyclical deposition processes as described herein may optionally be carried out in reaction chambers connected to a cluster tool. In a cluster tool, because each reaction chamber is dedicated to one type of process, the temperature of the reaction chamber in each module can be kept constant, which improves the throughput compared to a reaction chamber in which the substrate is heated up to the process temperature before each run. Additionally, in a cluster tool it is possible to reduce the time to pump the reaction chamber to the desired process pressure levels between substrates. In some embodiments of the disclosure, the exemplary cyclical deposition processes of the present disclosure may be performed in a cluster tool comprising multiple reaction chambers, wherein each individual reaction chamber may be utilized to expose the substrate to an individual precursor gas and the substrate may be transferred between different reaction chambers for exposure to multiple precursors gases, the transfer of the substrate being performed under a controlled ambient to prevent oxidation/contamination of the substrate. In some embodiments of the disclosure, the metallic gap-fill film cyclical deposition processes of the current disclosure may be performed in a cluster tool comprising multiple reaction chambers, wherein each individual reaction chamber may be configured to heat the substrate to a different temperature.

In some embodiments, the metallic gap-fill film cyclical deposition processes of the current disclosure may be performed in a single stand-alone reactor which may be equipped with a load-lock. In that case, it is not necessary to cool down the reaction chamber between each run.

Once the substrate is disposed within a suitable reaction chamber, such as, for example, an atomic layer deposition reaction chamber or a chemical vapor deposition reaction chamber, the substrate may be heated to a desired deposition temperature. In some embodiments, the exemplary cyclical deposition process 200 (FIG. 2) may be performed at a constant deposition temperature, i.e., substrate temperature. In alternative embodiments, the substrate may be heated to a first substrate temperature for contacting the substrate with the deposition precursors (e.g., a metal precursor and a nitrogen precursor) and the substrate may heated to a second substrate temperature, different from the first substrate temperature, for contacting the substrate with the halide growth inhibitor.

In some embodiments of the disclosure, the substrate may be heated to a deposition temperature (i.e., substrate temperature) of less than 600° C., or less than 500° C., or less than 400° C., or less than 300° C., or even less than 200° C. In some embodiments, the substrate may be heated to a deposition temperature between 200° C. and 600° C., or between 300° C. and 500° C., or between 350° C. and 480° C., or between 400° C. and 450° C.

In addition, to achieving a desired deposition temperature, the exemplary cyclical deposition process 200 may also regulate the pressure within the reaction chamber. For example, in some embodiments of the disclosure, the reaction chamber pressure may regulated to less than 300 Torr, or less than 200 Torr, or less than 100 Torr, or less than 50 Torr, or less than 25 Torr, or less than 10 Torr, or less than 5 Torr, or less than 3 Torr, or even less than 1 Torr. In some embodiments, the reaction chamber pressure may be regulated at a pressure between 1 Torr and 300 Torr, or between 1 Torr and 10 Torr, or between 1 Torr and 5 Torr, or between 1 Torr and 3 Torr.

Once the substrate is heated to a desired deposition temperature and the pressure within the reaction chamber has been regulated, the exemplary cyclical metallic gap-fill film deposition process 200 may proceed with a cyclical deposition phase 205 wherein the cyclical deposition phase 205 commences by means of a process block 220 comprising, contacting the substrate with a first vapor phase reactant comprising a metal precursor.

In some embodiments of the disclosure, the metal precursor may comprise a metal halide precursor, such as, for example, a metal chloride precursor, a metal iodide precursor, or a metal bromide precursor. In particular embodiments, the metal halide precursor may comprise at least one metal chloride precursor selected from the group comprising: titanium tetrachloride (TiCl₄), hafnium tetrachloride (HfCl₄), boron trichloride (BCl₃), aluminum trichloride (AlCl₃), silicon tetrachloride (SiCl₄), disilicon hexachloride (Si₂Cl₆), trisilicon octochloride (Si₃Cl₈), dichlorosilane (SiH₂Cl₂), NiCl₂(TMPDA), gallium monochloride (GaCl), gallium trichloride (GaCl₃), niobium pentachloride (NbCl₅), molybdenum tetrachloride (MoCl₄), molybdenum pentachloride (MoCl₅), molybdenum (V) trichloride oxide (MoOCl₃), molybdenum (VI) tetrachloride oxide (MoOCl₄), molybdenum (IV) dichloride dioxide (MoO₂Cl₂), indium trichloride (InCl₃), tantalum pentachloride (TaCl₅), tungsten hexachloride (WCl₆).

In some embodiments of the disclosure, the metal halide precursor may comprise a metal iodide precursor, such as, titanium tetraiodide (TiI₄), for example. In some embodiments, the metal halide precursor may comprise a metal bromide, such as, titanium tetrabromide, for example.

In some embodiments of the disclosure, contacting the substrate with a metal precursor may comprise contacting the substrate with the metal precursor for a time period of between about 0.01 seconds and about 60 seconds, or between about 0.05 seconds and about 10 seconds, or between about 0.1 seconds and about 5.0 seconds, or even between 0.2 seconds and 1 second. In addition, during the contacting of the substrate with the metal precursor, the flow rate of the metal precursor may be less than 2000 sccm, or less than 1500 sccm, or less than 500 sccm, or between 1 to 2000 sccm, or between 500 to 1500 sccm, or even between 1000 to 1400 sccm.

The cyclical deposition phase 205 of the exemplary cyclical deposition process 200 (FIG. 2) may continue by purging the reaction chamber. For example, excess metal precursor may be removed from the surface of the substrate by introducing an inert purge gas and exhausting the reaction chamber with the aid of a vacuum pump in fluid communication with the reaction chamber. The purge process may comprise a purge cycle, wherein the substrate surface is purged for a time period of less than 5 seconds, or less than 3 seconds, or less than 2 seconds, or even less than 1 second. In some embodiments, the substrate surface is purged for a time period between 0.1 seconds and 5 seconds.

Upon purging the reaction chamber the exemplary cyclical deposition process 200 (FIG. 2) may continue by means of a process block 230 which comprises, contacting the substrate with a second vapor phase reactant comprising at least one of: a nitrogen precursor, an oxygen precursor, a carbon precursor, or a silicon precursor. In particular embodiments, the metallic gap-fill film may comprise a metal nitride and the process block 230 may comprise, contacting the substrate with a nitrogen precursor.

In some embodiments of the disclosure, the nitrogen precursor comprises at least one of: molecular nitrogen (N₂), ammonia (NH₃), hydrazine (N₂H₄), a hydrazine derivative, or a nitrogen-based plasma. In some embodiments, the hydrazine derivative may comprise an alkyl-hydrazine including at least one of: tertbutylhydrazine (C₄H₉N₂H₃), methylhydrazine (CH₃NHNH₂), or dimethylhydrazine ((CH₃)₂N₂H₂). In some embodiments, the nitrogen-based plasma may be generated by the application of RF power to a nitrogen containing gas and the nitrogen-based plasma may comprise atomic nitrogen (N), nitrogen ions, nitrogen radicals, and excited species of nitrogen. In some embodiments, the nitrogen based plasma may further comprise additional reactive species, such as, by the addition of a further gas.

In some embodiments of the disclosure, the oxygen precursor comprises at least one of: water (H₂O), hydrogen peroxide (H₂O₂), ozone (O₃), sulfur trioxide (SO₃), or oxides of nitrogen, such as, for example, nitrogen monoxide (NO), nitrous oxide (N₂O), or nitrogen dioxide (NO₂). In some embodiments of the disclosure, the oxygen precursor may comprise an organic alcohol, such as, for example, isopropyl alcohol. In some embodiments, the oxygen precursor may comprise an oxygen based plasma, wherein the oxygen based plasma comprises atomic oxygen (O), oxygen ions, oxygen radicals, and excited oxygen species, and may be generated by the excitation (e.g., by application of RF power) of an oxygen containing gas. It should be noted that as used herein the term “vapor phase reactant” includes an excited plasma and the excited species comprising the plasma.

In some embodiments of the disclosure, the carbon precursor may comprise an organic precursor, such as, a metalorganic precursor, for example. In some embodiments, the metalorganic precursor may be selected from the group comprising: tetrakisdimethylamino titanium (TDMAT), tetrakisdiethylamino titanium (TDEAT), pentamethylcyclopentadienyltrimethoxy titanium (CpMe₅Ti(OMe)₃), titanium methoxide (Ti(OMe)₄), titanium ethoxide (Ti(OEt)₄), titanium isopropoxide (Ti(OPr)₄), or titanium butoxide (Ti(OBu)₄).

In some embodiments, a metalorganic precursor may utilized to provide a carbon component to the metallic gap-fill film as well as an additional metal component thereby depositing a ternary or quaternary metallic gap-fill film.

In some embodiments of the disclosure, the silicon precursor may comprise at least one of: silane (SiH₄), disilane (Si₂H₆), trisilane (Si₃H₈), tetrasilane (Si₄H₁₀), isopentasilane (Si₅H₁₂), or neopentasilane (Si₅H₁₂). In some embodiments, the silicon precursor may comprise a C1-C4 alkylsilane.

In some embodiments of the disclosure, the metallic gap-fill film may comprise at least one of a: metal nitride film, metal oxide film, metal carbide film, metal silicide film, metal sulfide film, metal selenide film, metal phosphide film, metal boride film, or mixtures and/or laminates thereof. In particular embodiments, the metallic gap-fill film may comprise at least one of a: transition metal oxide film, transition metal nitride film, transition metal silicide film, transition metal phosphide film, transition metal selenide film, transition metal boride film, or mixtures and/or laminates thereof.

In some embodiments of the disclosure, the metallic gap-fill film may comprise a titanium nitride film.

In some embodiments of the disclosure, the metallic gap-fill may comprise metallic ternary film, such as, for example, a ternary metal nitride film, a ternary metal oxide film, a ternary metal carbide film, a ternary metal silicide film, a ternary metal sulfide film, a ternary metal selenide film, a ternary metal phosphide film, a ternary metal boride film, or mixtures and/or laminates thereof. In some embodiments, the ternary metallic gap-fill film may comprise at least of: titanium aluminum nitride (TiAlN), titanium aluminum carbide (TiAlC), titanium niobium nitride (TiNbN), or titanium silicon nitride (TiSiN).

In some embodiments of the disclosure, contacting the substrate with the second vapor phase reactant may comprise, contacting the substrate with the second vapor phase reactant for a time period of between about 0.01 seconds and about 60 seconds, between about 0.05 seconds and about 10 seconds, or between about 0.1 seconds and about 5.0 seconds, or between 0.1 seconds and 5 seconds. In addition, during the contacting of the substrate with the second vapor phase reactant, the flow rate of the second vapor phase reactant may be less than 10,000 sccm, or less than 8000 sccm, or less than 6000 sccm, or less than 4000 sccm, or less than 2000 sccm, or less than 1000 sccm, or between 10 sccm to 20,000 sccm, or between 1000 sccm to 8000 sccm, or even between 5000 sccm to 70000 sccm.

Upon contacting the substrate with the second vapor phase reactant, the cyclical deposition phase 205 of exemplary cyclical deposition process 200 (FIG. 2) may proceed by purging the reaction chamber, as described previously herein and therefore not repeated in the interest of brevity.

Upon completion of the purge of the second vapor phase reactant from the reaction chamber, the cyclic deposition phase 205 may proceed by means of a process block 240 comprising, contacting the substrate with a halide growth inhibitor.

In some embodiments of the disclosure, the halide growth inhibitor comprises a vapor phase reactant. In some embodiments, the halide growth inhibitor comprises hydrochloric acid (HCl) vapor.

In some embodiments of the disclosure, the halide growth inhibitor may be sourced from both an internal source within the reaction chamber and an external source, remote from the reaction chamber, fluidly connected to the reaction chamber.

In some embodiments, at least a portion of the halide growth inhibitor may be formed within the reaction chamber, i.e., in-situ formation of the halide growth inhibitor. In some embodiments, at least a portion of the halide growth inhibitor employed during the cyclical deposition phase 205 of the exemplary cyclical deposition process 200, may be form as a reaction by-product.

As a non-limiting example, the first vapor phase reactant may comprise a metal halide, such as, titanium tetrachloride (TiCl₄), for example, and the second vapor phase reactant may comprise a nitrogen precursor, such as, ammonia (NH₃), for example. A reaction by-product formed by the reaction between the titanium tetrachloride precursor and the ammonia precursor may be hydrochloric acid (HCl) vapor, which in turn may be utilized as at least a partial source for the halide growth inhibitor.

In some embodiments, at least a portion of the halide growth inhibitor is introduced into the reaction from an external source vessel. For example, the halide growth inhibitor may comprise hydrochloric acid vapor (HCl) which is introduced into the reaction chamber from an external source via stainless gas lines which fluidly connect the external source vessel and reaction chamber. In some embodiments of the disclosure, the external source of the halide growth inhibitor may be pulsed into the reaction chamber, contacting the substrate with the halide growth inhibitor for a time period of between about 0.01 seconds and about 30 seconds, between about 0.05 seconds and about 10 seconds, or between about 0.1 seconds and about 5.0 seconds, or between 1.0 seconds and 4 seconds. In addition, during the contacting of the substrate with the halide growth inhibitor sourced from the external source, the flow rate of the halide growth inhibitor may be less than 500 sccm, or less than 250 sccm, or less than 100 sccm, or less than 50 sccm, or between 1 sccm to 500 sccm, or between 25 sccm to 250 sccm, or even between 50 sccm to 100 sccm.

In some embodiments of the disclosure, the halide growth inhibitor utilized in the unit deposition cycle of the exemplary cyclical deposition process 200 (FIG. 2) may establish a non-conformal cyclical deposition process, wherein the deposited film does not have a uniform average thickness across the surface of a non-planar substrate. For example, in some embodiments, the halide growth inhibitor may be employed to preferentially suppress metal gap-fill film deposition in particular regions of a gap feature thereby resulting a non-conformal deposition process. Therefore, in some embodiment, the exemplary cyclical deposition process 200 (FIG. 2) comprises a non-conformal deposition process, wherein the non-conformal deposition process preferentially deposits a metallic gap-fill film in a gap feature at a distal location from an opening of the gap feature. In some embodiments, the non-conformal deposition process preferentially deposits a metal nitride film in a gap feature at a distal location from an opening of the gap feature.

In some embodiments of the disclosure, the non-conformal deposition may be modified to enhance preferential deposition of a metallic gap-fill film at a distal location from the opening of a gap feature by at least increasing the partial pressure of the halide growth inhibitor within the reaction chamber. In some embodiment, the partial pressure of the halide growth inhibitor may be controlled between 1 mTorr and 100 mTorr.

In some embodiments, the non-conformal deposition may be modified to enhance preferential deposition of a metallic gap-fill film at a distal location from the opening of a gap feature by at least increasing the period of contact between the substrate and halide growth inhibitor. In some embodiments, the non-conformal deposition may be modified to enhance preferential deposition of a metallic gap-fill film at a distal location from the opening of a gap feature by at least increasing the flow rate of the halide growth inhibitor sourced from the external source vessel.

In some embodiments of the disclosure, the gap feature may comprise a vertical gap feature and the non-conformal deposition process may preferentially deposit a metallic gap-film at the base of the vertical gap feature thereby filling the vertical gap feature with a metallic gap-fill film by means of a bottom-up deposition process. In some embodiments of the disclosure, the gap feature may comprise a vertical gap feature and the non-conformal deposition process may preferentially deposit a metal nitride film at the base of the vertical gap feature thereby filling the vertical gap feature with a metal nitride film by means of a bottom-up deposition process.

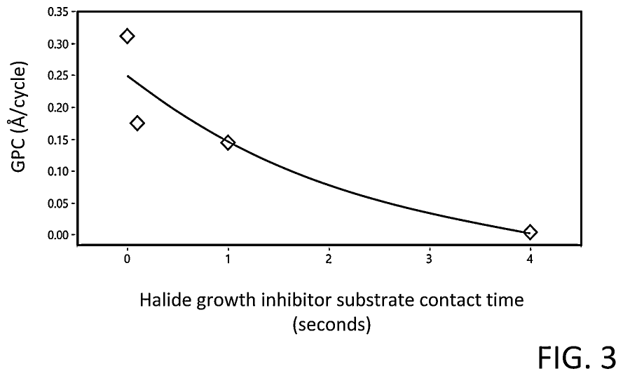

As a non-limiting example of the cyclical deposition processes of the present disclosure, FIG. 3 illustrates exemplary experimental data demonstrating the decrease in growth rate per cycle (GPC) (i.e., number of repetitions of the unit cycle) for a cyclical deposition process as a function of the contact time between a substrate surface and a halide growth inhibitor. This non-limiting experiment data was obtained employing titanium tetrachloride (TiCl₄) as the metal precursor, ammonia (NH₃) as the nitrogen precursor, and hydrochloric acid vapor (HCl) as the halide growth inhibitor, during a cyclical deposition of a titanium nitride film. Examination of the experiment data in FIG. 3 clearly demonstrates that as the time period of exposure between the substrate surface and hydrochloric acid vapor growth inhibitor is increased there is a clear reduction in the growth rate per cycle (GPC) of the titanium nitride film, demonstrating the effectiveness of the halide growth inhibitor in suppressing growth on the substrate surface.

Upon contacting the substrate with the halide growth inhibitor, the cyclical deposition phase 205 of exemplary cyclical deposition process 200 (FIG. 2) may proceed by purging the reaction chamber, as described previously herein and therefore not repeated in the interest of brevity.

After completion of the purge cycle, the cyclical deposition phase 205 of exemplary cyclical deposition process 200 may proceed by means of a decision gate 250, wherein the decision gate 250 is dependent on the thickness of the metallic gap-fill film within the gap feature, i.e., decision gate determined on whether the gap feature is completely filled with the metallic gap-fill film.

For example, if the metallic gap-fill film is deposited at an insufficient thickness to completely fill the gap feature, then the cyclical deposition phase 205 may be repeated by returning to the process block 220 and continuing through a further unit deposition cycle, wherein a unit deposition cycle may comprise: contacting the substrate with a metal precursor (process block 220), purging the reaction chamber, contacting the substrate with second vapor phase reactant, such as, a nitrogen precursor, for example (process block 230), again purging the reaction chamber, contacting the substrate with the halide growth inhibitor (process 240), and again purging the reaction chamber. The unit deposition cycle of the exemplary cyclical deposition process 200 may be repeatedly performed until the average film thickness of the metallic gap-fill film is sufficient to completely fill the one or more gap features disposed in and/or the surface of the substrate.

It should be appreciated that in some embodiments of the disclosure, the order of contacting of the substrate with the first vapor phase reactant (e.g., a metal chloride), the second vapor phase reactant (e.g., a nitrogen precursor), and the halide growth inhibitor may be different to that described herein and illustrated in FIG. 2. It should be appreciated that any conceivable sequence of the contacting processes, purge cycles, and repetitions thereof, is assumed as part of the present disclosure. For example, an alternative unit deposition cycle process sequence may comprise: contacting the substrate with metal precursor (e.g., a metal halide), purging the reaction chamber, contacting the substrate with the halide growth inhibitor, purging the reaction chamber, contacting the substrate with the second vapor phase reactant (e.g., a nitrogen precursor), and again purging the reaction chamber.

Upon completion of cyclical deposition phase 205, the exemplary cyclical deposition process 200 (FIG. 2) may exit by means of a process block 250 and the substrate comprising one or more gap features filled with the metallic gap-fill film may be further processed to fabricate semiconductor device structures.

In some embodiments of the disclosure, the metallic gap-fill film may be deposited to an average film thickness of between 10 Å and 30 Å. In some embodiments, the metallic gap-fill film comprises a titanium nitride film deposited to an average film thickness of between 10 Å and 30 Å.

In some embodiments of the disclosure, the metallic gap-fill film may be physically continuous at an average film thickness of less than 10 Å. In some embodiments, the metallic gap-fill film comprises a titanium nitride film which may be physically continuous at an average film thickness of less than 10 Å. In addition, in some embodiment, the metallic gap-fill film may comprise a titanium nitride film with an average film thickness of less than 60 Å and an electrical resistivity of less than 250 μΩ-cm.

In some embodiments of the disclosure, the metallic gap-fill film may have an atomic-% of halide impurities of less than 1 atomic-%. For example, the metallic gap-film may comprise a titanium nitride film having an atomic-% of halide impurities of less than 1 atomic-%. The atomic-% of impurities in the metallic gap-fill films of the present disclosure may be determined by Rutherford backscattering spectrometry (RBS), for example.

In some embodiments of the disclosure, the metallic gap-fill film may have an average r.m.s. surface roughness (Rₐ) of less than 0.3 Å. For example, the metallic gap-fill film may comprise a titanium nitride film having an average r.m.s. surface roughness (Rₐ) of less than 0.3 Å. The surface roughness of the surfaces of the metallic gap-fill films deposited according to the embodiments of the disclosure may be determined by atomic force microscopy (AFM) over a surface area of 100 microns×100 microns, for example.

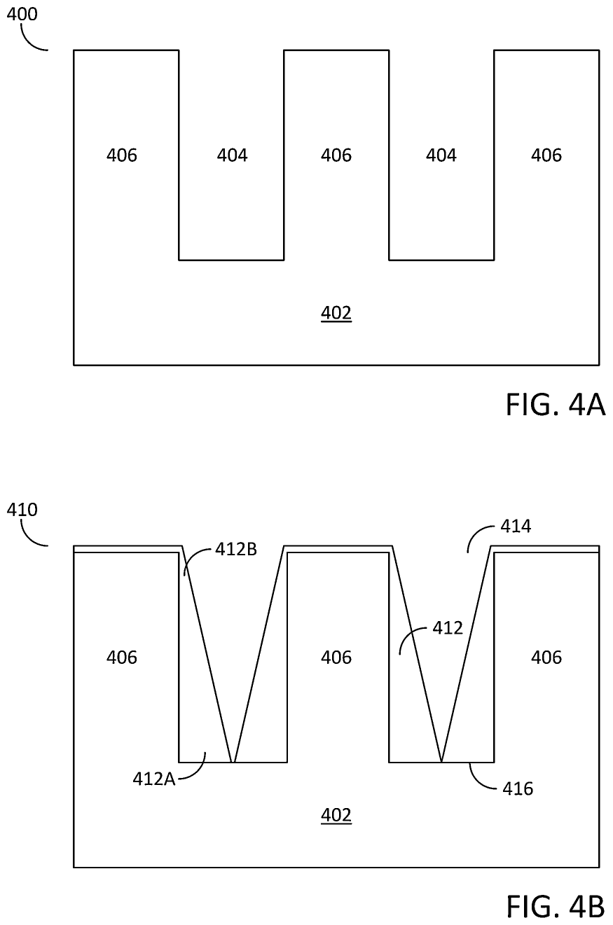

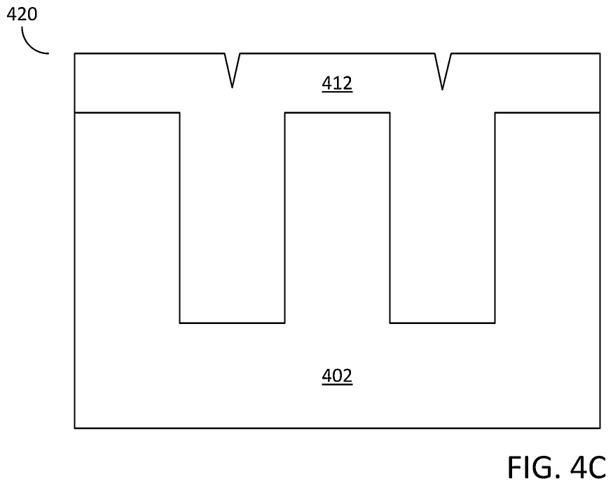

A non-limiting example of the cyclical deposition processes of the present disclosure are illustrated with reference to FIGS. 4A-4C which illustrate simplified cross-sectional schematic diagrams of semiconductor structures formed during an exemplary cyclical deposition process of the present disclosure.

In more detail, FIG. 4A illustrates a semiconductor structure 400 comprising a substrate 402 including a number of vertical gap features 404 disposed between vertical raised regions of the substrate 406. It should be noted that the geometry of the vertical gap features illustrated in FIG. 4A is non-limiting, i.e., the cyclical gap fill deposition process of the present disclosure are not limiting to vertical gap feature comprising sidewalls perpendicular to a horizontal base.

FIG. 4B illustrates a semiconductor structure 410 comprising the structure 400 (FIG. 4A) after a number of repeated unit cycles of the cyclical deposition processes of the current disclosure have been performed to deposit a metallic gap-fill film 412. As illustrated in FIG. 4B the metallic gap-fill film 412 is preferentially deposited in regions of the vertical gap features distal from the openings of the vertical gap features 414. For example, the base regions of the vertical gap features 416 are disposed distal to the openings of the vertical gap features 414 and the metallic gap-fill film 412 is deposited preferentially within the base regions 416 of the vertical gap fill features compared with the opening regions 414 of the vertical gap features, as illustrated by the greater thickness of the metallic gap fill film 412A in the regions proximate to the base regions 416 compared with the lower thickness of the metallic gap fill film 412B in the regions distal to the base regions, i.e., proximate to the vertical gap feature opening regions 414. Therefore, as illustrated in FIG. 4B, the metallic gap-fill film 412 fills the vertical gap features by means of bottom-up deposition, i.e., a preferential initial deposition proximate to base regions 416 and subsequent repeated unit deposition cycles fill the vertical gap features up towards the vertical gap feature opening 414.

FIG. 4C illustrates a semiconductor structure 420 which demonstrates that complete fill of the vertical gap features with the metallic gap-fill metal 412.

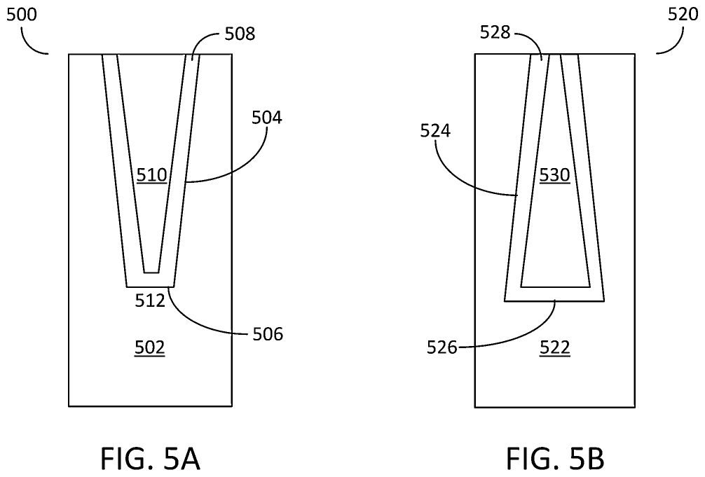

Further non-limiting examples of the cyclical deposition methods of the current disclosure and the associated metallic gap-fill films are illustrated in FIGS. 5A and 5B. In more detail, FIGS. 5A and 5B illustrate simplified cross-section schematic diagrams of exemplary semiconductor structures including vertical gap features with differing geometries filled with a metallic gap-fill film according to the embodiments of the disclosure.

FIG. 5A illustrates a semiconductor structure 500 comprising a substrate 502 including a vertical gap feature 504 comprising a v-shaped tapered trench structure with opposing inclined sidewalls that plateau to a flat base surface 506. In some embodiments the semiconductor structure 500 may comprise a portion of a partially fabricated semiconductor device structure, such as, a partially fabricated metal-oxide-semiconductor transistor structure. In some embodiments, a number of addition films 508 may deposited over the gap feature prior to deposition of the metallic gap-fill film 510. As a non-limiting example, the semiconductor structure 500 may comprise a portion of a logic device and the addition films disposed between the substrate 502 the metallic gap-fill film 510 may comprise one or more of an oxide interface film, a high-k dielectric film, a metal nitride blocking, and a work function metallic film. As illustrated in FIG. 5A, the metallic gap-fill film 510 is deposited directly over the additional films 505 and completely fills the vertical trench structure 504 without the formation of visible seam within the vertical trench (as would be determined experimental via high magnificent electron microscopy, as previously described herein).

In some embodiments of the disclosure, metallic gap-fill film may comprise at least a portion of a gate stack, the gate stack being disposed over at least a portion of a channel region of a metal-oxide-semiconductor transistor structure. For example, with reference to FIG. 5A, the substrate 502 may comprise a channel region 512 and the additional films 508 together with the metallic gap-fill film 510 may comprises at least a portion of a gate stack.

In some embodiments of the disclosure, the exposed deposition surfaces of the additional films 508 (i.e., prior to metallic gap-fill film deposition) may comprise metallic surfaces, such as vertical metallic surfaces and horizontal metallic surfaces. Therefore, in some embodiments, the metallic gap-fill film is cyclically deposited directly in vertical gap feature comprising both metallic vertical surfaces and horizontal metallic surfaces.

FIG. 5B illustrates a further semiconductor structure 520 comprising a substrate 522 including a vertical gap feature 524 comprising a re-entrant trench structure with opposing inclined sidewalls that plateau to a flat base surface 526. As previously described with reference to FIG. 5A, the semiconductor structure 520 may comprise a portion a partially fabricated metal-oxide-semiconductor transistor structure and may include the addition films 528 deposited over the gap feature prior to deposition of the metallic gap-fill film 530. As described previously herein the addition films 528 disposed between the substrate 522 and the metallic gap-fill film 530 may comprise one or more of: an oxide interface film, a high-k dielectric film, a metal nitride blocking, and a work function metallic film. As illustrated in FIG. 5B, the metallic gap-fill film 530 is deposited directly over the additional films 528 and completely fills the vertical trench structure without the formation of visible seam within the vertical trench (as would be determined experimental via high magnificent electron microscopy, as previously described herein).

The embodiments of the disclosure may also comprise cyclical deposition apparatus configured for performing the metallic gap-fill film deposition process described herein. In some embodiments, the cyclical deposition apparatus may comprise a reaction chamber configured for performing cyclical deposition process, such as, for example, reaction chambers configured for performing atomic layer deposition and/or cyclical chemical vapor deposition. In such embodiments, the cyclical deposition apparatus may include two of more precursor source vessels fluidly connected to a reaction chamber. For example, the two or more precursor source vessel may comprise: a metal halide precursor source, and one of a nitrogen precursor source, an oxygen precursor source, a carbon precursor source, and a silicon precursor source. In addition, a further additional source vessel may be fluidly connected to the reaction chamber, wherein the additional source vessel contains a halide growth inhibitor such as, hydrochloric acid, for example.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combination of the elements described, may become apparent to those skilled in the art from the description. Such modifications and embodiments are also intended to fall within the scope of the appended claims.

What is claimed is:

1. A method for filling a gap feature on a substrate surface, the method comprising:
providing a substrate comprising a gap feature into a reaction chamber; and
filling the gap feature with a metal nitride film by performing one or more unit cycles of a cyclical deposition process, wherein a unit cycle of the cyclical deposition process comprises:
contacting the substrate with a metal precursor;
contacting the substrate with a nitrogen precursor; and
contacting the substrate with a halide growth inhibitor.

2. The method of claim 1, wherein the metal nitride film comprises at least one of a: titanium nitride film, hafnium nitride film, boron nitride film, aluminum nitride film, silicon nitride film, gallium nitride film, niobium nitride film, molybdenum nitride film, indium nitride film, tantalum nitride film, or a tungsten nitride film.

3. The method of claim 2, wherein the metal nitride film comprises a titanium nitride film.

4. The method of claim 1, wherein the metal nitride film fills the gap feature without the formation of a seam.

5. The method of claim 1, wherein the cyclical deposition process comprises at least one of: an atomic layer deposition process, or a cyclical chemical vapor deposition process.

6. The method of claim 1, wherein the metal precursor comprises a metal halide precursor.

7. The method of claim 6, wherein the metal halide precursor comprises a metal chloride precursor.

8. The method of claim 7, wherein the metal chloride precursor comprises at least one of: titanium tetrachloride (TiCl₄), hafnium tetrachloride (HfCl₄), boron trichloride (BCl₃), aluminum trichloride (AlCl₃), silicon tetrachloride (SiCl₄), disilicon hexachloride (Si₂Cl₆), trisilicon octochloride (Si₃Cl₈), dichlorosilane (SiH₂Cl₂), NiCl₂(TMPDA), gallium monochloride (GaCl), gallium trichloride (GaCl₃), niobium pentachloride (NbCl₅), molybdenum tetrachloride (MoCl₄), molybdenum pentachloride (MoCl₅), molybdenum (V) trichloride oxide (MoOCl₃), molybdenum (VI) tetrachloride oxide (MoOCl₄), molybdenum (IV) dichloride dioxide (MoO₂Cl₂), indium trichloride (InCl₃), tantalum pentachloride (TaCl₅), tungsten hexachloride (WCl₆).

9. The method of claim 1, wherein the nitrogen precursor comprises at least one of: molecular nitrogen (N₂), ammonia (NH₃), hydrazine (N₂H₄), a hydrazine derivative, or a nitrogen-based plasma.

10. The method of claim 1, wherein the halide growth inhibitor is sourced from both an internal source within the reaction chamber and an external source, remote from the reaction chamber, fluidly connected the reaction chamber.

11. The method of claim 1, wherein at least a portion of the halide growth inhibitor is formed in-situ within the reaction chamber.

12. The method of claim 1, wherein at least a portion of the halide growth inhibitor is introduced into the reaction chamber from an external source vessel.

13. The method of claim 1, wherein the cyclical deposition process comprises a non-conformal deposition process, wherein the non-conformal deposition process preferentially deposits the metal nitride film in the gap feature at a distal location from an opening of the gap feature.

14. The method of claim 13, wherein the non-conformal deposition process is modified to enhance preferential deposition of the metal nitride film at the distal location from the opening of the gap feature by at least increasing a partial pressure of the halide growth inhibitor within the reaction chamber.

15. The method of claim 14, wherein the partial pressure of the halide growth inhibitor within the reaction chamber is controlled between 1 mTorr and 100 mTorr.

16. The method of claim 13, wherein the gap feature comprises a vertical gap feature and the non-conformal deposition process preferentially deposits the metal nitride film at a base of the vertical gap feature thereby filling the vertical gap feature with the metal nitride film by means of a bottom-up deposition process.

17. The method of claim 1, wherein the cyclical deposition process is performed at a deposition temperature between 200° C. and 500° C.

18. The method of claim 3, wherein the titanium nitride film has an average film thickness of between 10 and 30 Å.

19. The method of claim 3, wherein the titanium nitride film is physically continuous at an average film thickness of less than 10 Å.

20. The method of claim 3, wherein the titanium nitride film has an average film thickness of less than 60 Å and an electrical resistivity of less than 250 μΩ-cm.

21. The method of claim 3, wherein the titanium nitride film has atomic-% of halide impurities of less than 1 atomic-%.

22. The method of claim 3, wherein the titanium nitride film has an average r.m.s. surface roughness (Ra) of less than 0.3 Å.

23. The method of claim 1, wherein the metal nitride film comprises at least a portion of a metal gate stack, the metal gate stack being disposed over at least a portion of a channel region of a metal-oxide-semiconductor transistor structure.

24. The method of claim 23, wherein the metal nitride film is cyclically deposited directly in a vertical gap feature comprising both vertical metallic surfaces and horizontal metallic surfaces.

25. A method for filling a vertical gap feature on a substrate surface, the method comprising:
providing a substrate comprising a vertical gap feature into a reaction chamber configured for a cyclical deposition process;
depositing a metal nitride film within the vertical gap feature by performing repeated unit cycles of a non-conformal cyclical deposition process, wherein a unit cycle of the non-conformal cyclical deposition process comprises:
contacting the substrate with a metal halide precursor;
contacting the substrate with a nitrogen precursor; and
contacting the substrate with a halide growth inhibitor; and
filling the vertical gap feature with the metal nitride film;
wherein the halide growth inhibitor is provided from both an internal source within the reaction chamber and an external source, remote from the reaction chamber, fluidly connected to the reaction chamber.

26. The method of claim 25, wherein the non-conformal cyclical deposition process preferentially deposits the metal nitride film proximate to a base region of the vertical gap feature thereby filling the vertical gap feature with the metal nitride film by means of bottom-up deposition process.

27. A method for filling a gap feature on a substrate surface, the method comprising:
providing a substrate comprising a gap feature into a reaction chamber configured for a cyclical deposition process;
depositing a metallic gap-fill film comprising at least one of a metal nitride film, a metal oxide film, a metal carbide film, or metal silicide film, within the gap feature by performing repeated unit cycles of a non-conformal cyclical deposition process, wherein a unit cycle of the non-conformal cyclical deposition process comprises:
contacting the substrate with a metal halide precursor;
contacting the substrate with at least one of a nitrogen precursor, an oxygen precursor, a carbon precursor, or a silicon precursor; and
contacting the substrate with a halide growth inhibitor; and
filling the gap feature with the metallic gap-fill film;
wherein the halide growth inhibitor is provided from both an internal source within the reaction chamber and an external source, remote from the reaction chamber, fluidly connected to the reaction chamber.

28. The method of claim 27, wherein the metallic gap-fill films comprise a ternary metal gap-fill film.

29. A semiconductor device structure including a gap feature filled with a metal nitride film by the method of claim 1.

30. A semiconductor device structure a gap feature filled with a metal compound film by the method of claim 27.

31. A cyclical deposition apparatus configured to perform the method of claim 1.
